(19) United States
(12) Patent Application Publication
(10) Pub. No.: US 2016/0343661 A1
(43) Pub. Date: Nov. 24, 2016

(54) STRUCTURE FOR COUPLING METAL LAYER INTERCONNECTS IN A SEMICONDUCTOR DEVICE

(71) Applicant: QUALCOMM Incorporated, San Diego, CA (US)

(72) Inventors: Mukul GUPTA, San Diego, CA (US); Xiangdong CHEN, San Diego, CA (US); Ohsang KWON, San Diego, CA (US); Stanley Seungchul SONG, San Diego, CA (US); Kern RIM, San Diego, CA (US); John Jianhong ZHU, San Diego, CA (US)

(21) Appl. No.: 15/159,744

(22) Filed: May 19, 2016

Related U.S. Application Data
(60) Provisional application No. 62/165,799, filed on May 22, 2015.

(51) Int. Cl. H01L 23/535; H01L 27/092; H01L 29/45; H01L 27/02

(52) U.S. Cl. CPC H01L 23/535; H01L 27/0207; H01L 27/092; H01L 29/45

(57) ABSTRACT

A MOS device includes a first interconnect extending in a first direction, the first interconnect being configured in a metal layer. The MOS device further includes a second interconnect extending in the first direction parallel to the first interconnect, the second interconnect being configured in the metal layer. The MOS device further includes a gate interconnect extending in a second direction orthogonal to the first direction, the gate interconnect being situated in a first layer below the metal layer, wherein the gate interconnect is coupled to the first interconnect by a first via. The MOS device further includes a third interconnect extending in the second direction, the third interconnect being coupled to both the first and second interconnects, wherein the third interconnect is coupled to the first interconnect by a second via, and wherein the second via contacts the first via.

### CROSS-REFERENCE TO RELATED APPLICATION(S)

This application claims the benefit of U.S. Provisional Application Ser. No. 62/165,799, entitled “STRUCTURE FOR COUPLING METAL LAYER INTERCONNECTS IN A SEMICONDUCTOR DEVICE” and filed on May 22, 2015, which is expressly incorporated by reference herein in its entirety.

### BACKGROUND

Field

The present disclosure relates generally to a structure for coupling metal layer interconnects in a semiconductor device.

Background

As semiconductor devices are fabricated at smaller sizes, manufacturers of semiconductor devices are finding it more difficult to integrate larger amounts of devices on a single chip. Furthermore, modern processing technologies are imposing a greater number of restrictions with respect to semiconductor device layout designs. For example, an interconnect routed in the M1 layer may be restricted from forming a jog in the M1 layer when certain processing technologies are used. As such, improvements to semiconductor layout designs are needed to overcome such restrictions.

### SUMMARY

In an aspect of the disclosure, a metal oxide semiconductor (MOS) device includes a first interconnect extending in a first direction, the first interconnect being configured in a metal layer. The MOS device further includes a second interconnect extending in the first direction parallel to the first interconnect. In an aspect, the second interconnect may be configured in the metal layer. The MOS device further includes a gate interconnect extending in a second direction orthogonal to the first direction. In a further aspect, the gate interconnect may be situated in a first layer below the metal layer. In yet another aspect, the gate interconnect may be coupled to the first interconnect by a first via. The MOS device further includes a third interconnect extending in the second direction, the third interconnect being coupled to both the first and second interconnects, wherein the third interconnect is coupled to the first interconnect by a second via, and wherein the second via contacts the first via.

In an aspect of the disclosure, a method of operation of a MOS device includes flowing a current through a first interconnect extending in a first direction, the first interconnect being configured in a metal layer. The method further includes flowing the current through a second interconnect extending in a second direction orthogonal to the first direction, the second interconnect being coupled to the first interconnect. The method further includes flowing the current through a third interconnect extending in the first direction parallel to the first interconnect, the third interconnect being configured in the metal layer, the third interconnect being coupled to the second interconnect by a first via. The method further includes flowing the current through a gate interconnect extending in the second direction, the gate interconnect being situated in a first layer below the metal layer, wherein the gate interconnect is coupled to the third interconnect by a second via, and wherein the second via contacts the first via.

In an aspect of the disclosure, a MOS device includes first means for flowing a current, the first means extending in a first direction, the first means being configured in a metal layer. The MOS device further includes second means for flowing the current, the second means extending in a second direction orthogonal to the first direction, the second means being coupled to the first means. The MOS device further includes third means for flowing the current, the third means extending in the first direction parallel to the first means, the third means being configured in the metal layer, the third means being coupled to the second means by a first via. The MOS device further includes fourth means for flowing the current, the fourth means extending in the second direction, the fourth means being situated in a first layer below the metal layer, wherein the fourth means is coupled to the third means by a second via, and wherein the second via contacts the first via.

### BRIEF DESCRIPTION OF THE DRAWINGS

FIG. 1 is a diagram of an example MOS device illustrating routing of M1 layer interconnects and M2 layer interconnects.

FIG. 2 is a diagram illustrating a top view of an example MOS device.

FIG. 3A is a diagram illustrating a top view of an example MOS device in accordance with various aspects of the disclosure.

FIG. 3B is a first diagram illustrating a cross-sectional view of the exemplary MOS device at section A-A.

FIG. 3C is a second diagram illustrating a cross-sectional view of the exemplary MOS device at section A-A.

FIG. 3D is a third diagram illustrating a cross-sectional view of the exemplary MOS device at section A-A.

FIG. 4 is a flow chart of an exemplary method.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

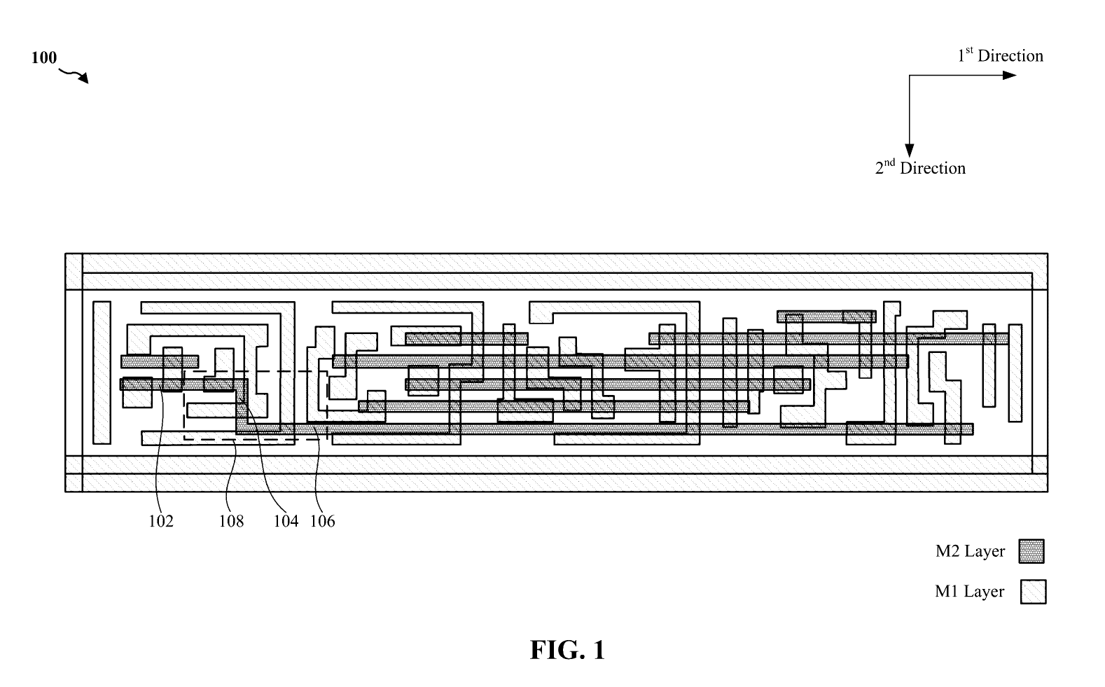

FIG. 1 is an exemplary layout diagram 100 for a MOS device. As shown in FIG. 1, layout diagram 100 illustrates routing of metal one (M1) layer interconnects and metal two (M2) layer interconnects. In the aspect of FIG. 1, the M2 layer has a preferred direction, such as the first direction indicated in the top right corner of FIG. 1. When an M2 layer interconnect is routed in a direction other than the preferred direction, the M2 layer interconnect may form a jog. Such a jog may be implemented for efficient use of metal resources and/or to achieve long signal routes in the MOS device 100. For example, as shown in FIG. 1, a first portion 102 of an M2 layer interconnect is routed in the first direction (e.g., the preferred direction). As further shown in FIG. 1, and with reference to region 108, a second portion 104 of the M2 layer interconnect is routed in the second direction. As further shown in FIG. 1, a third portion 106 of the M2 layer interconnect is routed in the first direction. In the configuration of FIG. 1, the second portion 104 of the M2 layer interconnect forms a jog along the second direction. Since the jog formed by the second portion 104 is not in the preferred direction of the M2 layer, other M2 layer interconnects must typically be spaced farther apart from the region (e.g., region 108) that includes the jog. As such, the configuration of FIG. 1 may result in an increase in area consumed on the MOS device 100 as compared to earlier MOS processing technologies in which the design rules allow closer spacing between the jog and nearby M2 layer interconnects. Moreover, certain MOS processing technologies (e.g., 10 nm node) may not allow any jogs in the M2 layer interconnects.

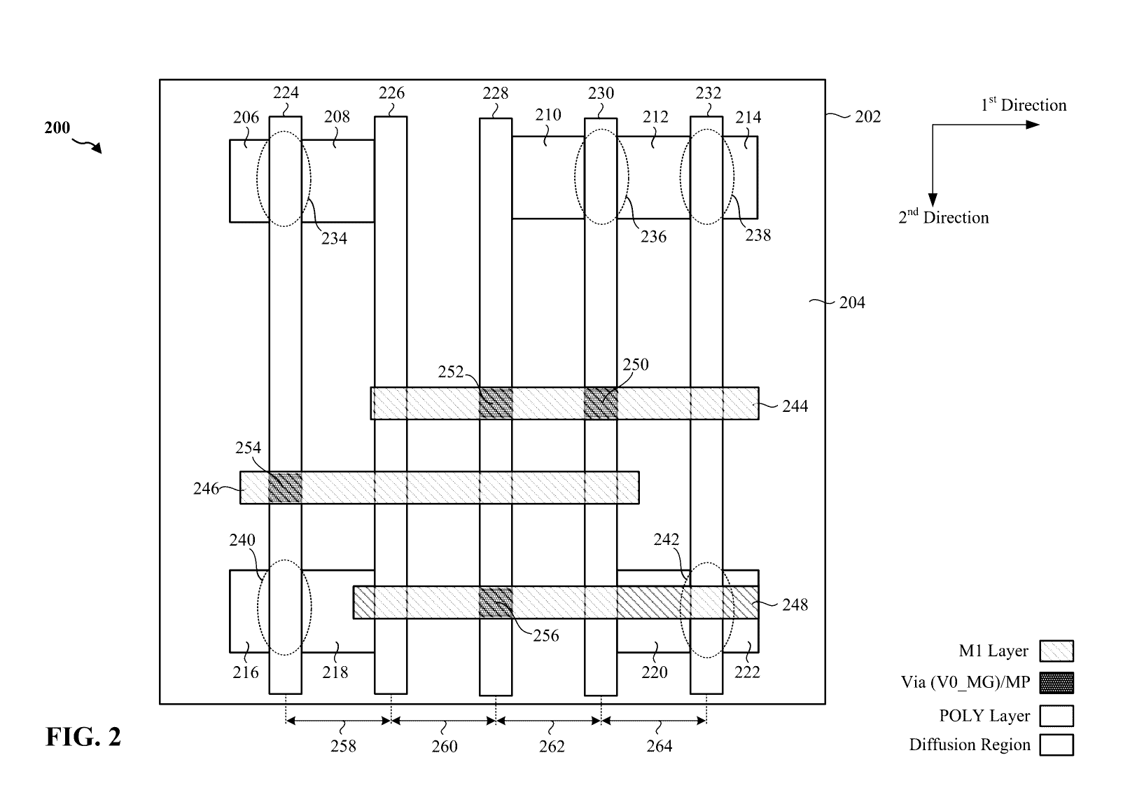

FIG. 2 is a diagram 200 illustrating a top view of an example MOS device 202. It should be understood that diagram 200 is a representation of the various masks that may be used for fabricating the features of the MOS device 202. For example, each mask may correspond to various features that are to be configured in a particular layer (e.g., interconnects, vias, etc.) of the MOS device 202. Therefore, diagram 200 concurrently shows a number of layers of the MOS device 202 in an overlaid manner for ease of illustration and understanding of the disclosure.

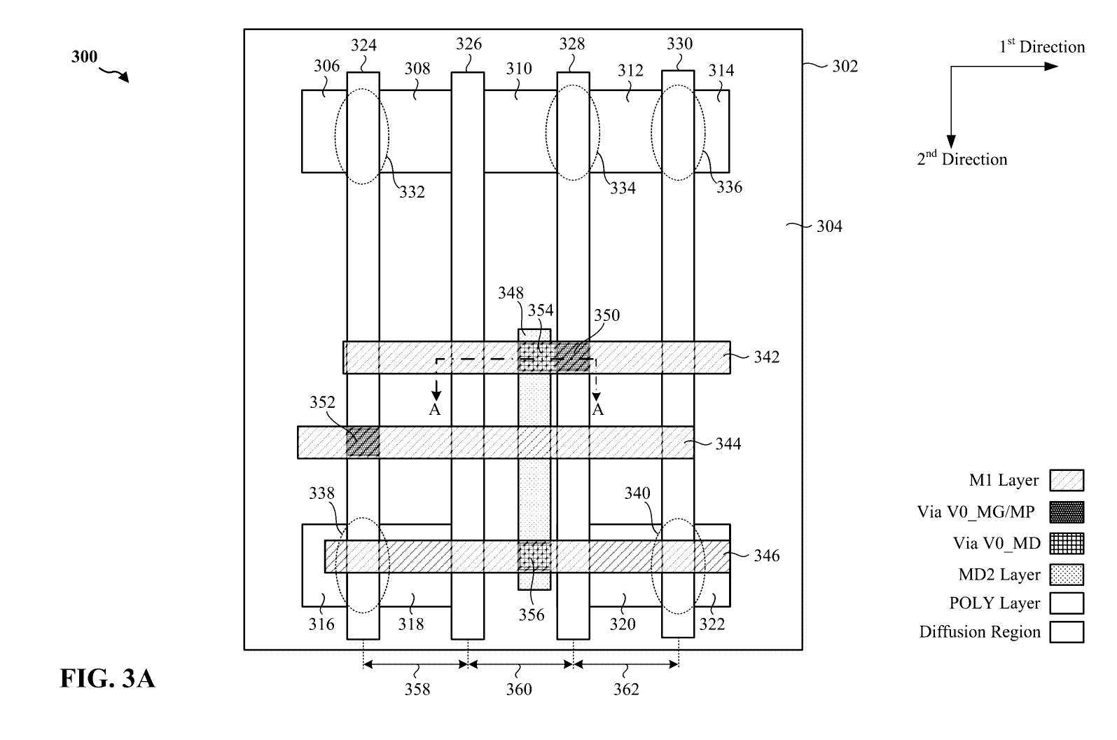

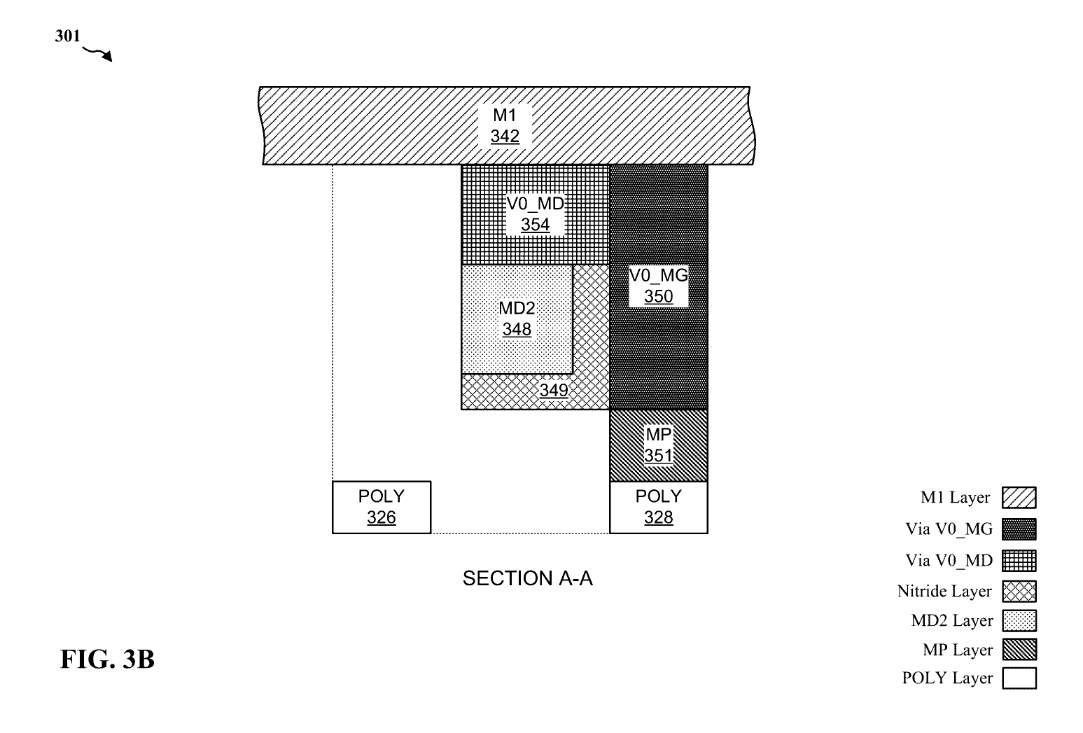

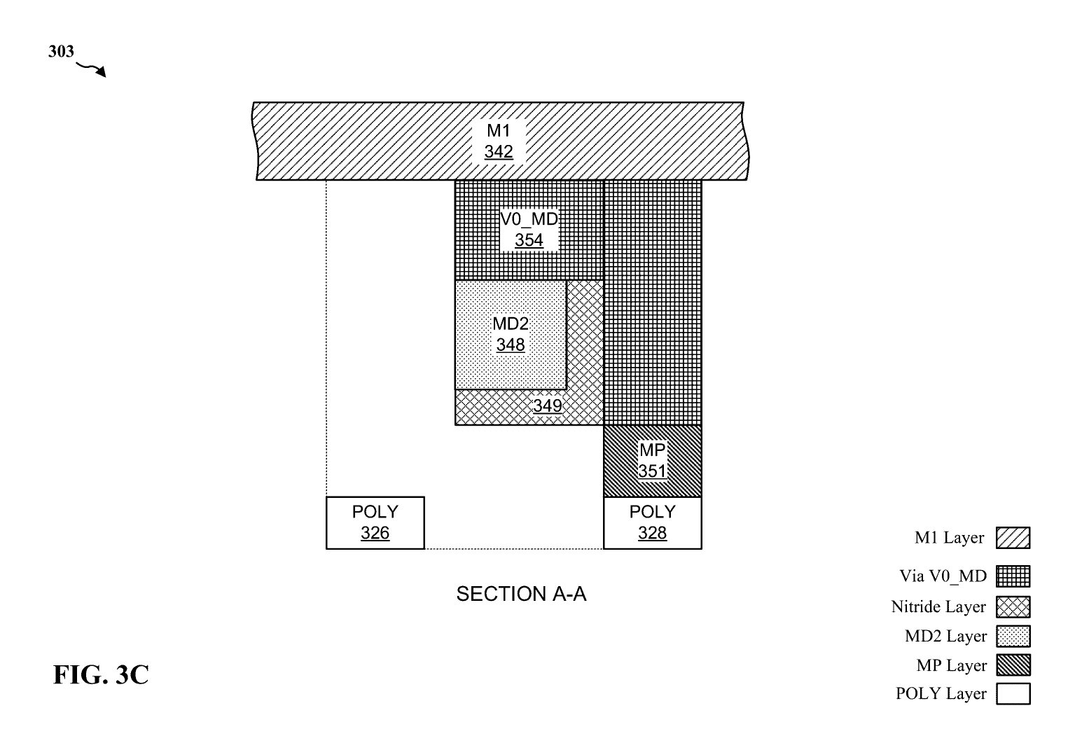

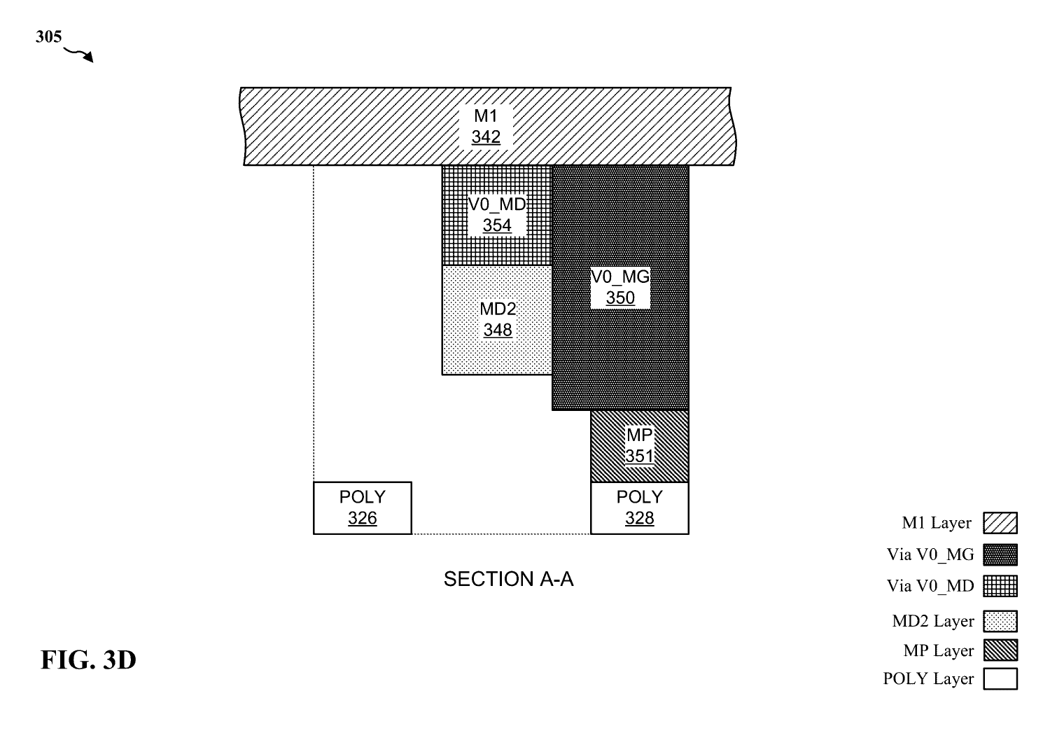

MOS device 202 has a substrate surface 204 and diffusion regions 206, 208, 210, 212, 214, 216, 218, 220, and 222. For example, diffusion regions 206, 208, 210, 212, and 214 may be P diffusion regions, and diffusion regions 216, 218, 220, and 222 may be N diffusion regions. The MOS device 202 includes gate interconnects 224, 226, 228, 230, and 232. In an aspect, the gate interconnects 224, 226, 228, 230, and 232 may be configured in a POLY layer and may be referred to as POLY layer gate interconnects 224, 226, 228, 230, and 232. In some process technologies, the gate interconnects 224, 226, 228, 230, and 232 may be formed of metal. However, in other process technologies, the gate interconnects 224, 226, 228, 230, and 232 may be entirely polysilicon or may be polysilicon with a metal top layer. The POLY layer gate interconnects 224, 226, 228, 230, and 232 extend in a second direction as indicated in the top right corner of FIG. 2. In the example configuration of FIG. 2, the POLY layer gate interconnects 224, 230, and 232 are configured as transistor gates. For example, POLY layer gate interconnect 224 is configured as a transistor gate for pMOS transistor 234 and nMOS transistor 240, POLY layer gate interconnect 230 is configured as a transistor gate for pMOS transistor 236, and POLY layer gate interconnect 232 is configured as a transistor gate for pMOS transistor 238 and nMOS transistor 242. POLY layer gate interconnects 226 and 228 are configured as dummy POLY layer gate interconnects. A dummy POLY layer gate interconnect may refer to a POLY layer gate interconnect that is not configured as a transistor gate for a transistor. As shown in FIG. 2, the MOS device 202 further includes M1 layer interconnects 244, 246, and 248 configured in the M1 layer. As shown in FIG. 2, the M1 layer interconnects 244, 246, and 248 extend in the first direction. In the configuration of FIG. 2, the M1 layer interconnect 246 is coupled to the POLY layer gate interconnect 224 through via (V0_MG) and a metal POLY (MP) interconnect 254 (see, for example, FIG. 3B for a cross-sectional view). In the aspects disclosed herein, the term V0_MG refers to a via that is formed using metal and that couples an interconnect in a metal layer to an interconnect in a POLY layer. The M1 layer interconnect 244 is coupled to the POLY layer gate interconnect 230 through via (V0_MG) and MP interconnect 250. The M1 layer interconnect 244 is further coupled to the POLY layer gate interconnect 228 through via (V0_MG) and MP interconnect 252. The POLY layer gate interconnect 228 is connected to the M1 layer interconnect 248 through via (V0_MG) and MP interconnect 256. The vias (V0_MG) 250, 252, 254, and 256 are situated above the POLY layer and below the M1 layer.

In the configuration of FIG. 2, the POLY layer gate interconnect 228 serves as a jog along the second direction to couple the M1 layer interconnect 244 to the M1 layer interconnect 248. Consequently, the POLY layer gate interconnect 228 is rendered a dummy POLY interconnect. Such use of the POLY layer gate interconnect 228 in the configuration of FIG. 2 consumes a significant amount of area on the MOS device 202. For example, the area consumed on the MOS device 202 may be represented in grid units, such as grid units 258, 260, 262, and 264. In the example configuration of FIG. 2, each of the grid units 258, 260, 262, and 264 indicates the spacing required between two adjacent POLY layer gate interconnects. In an aspect, the grid units 258, 260, 262, and 264 are substantially equal. Therefore, in the example configuration of FIG. 2, the MOS device 202 including the dummy POLY layer gate interconnects (e.g., POLY layer gate interconnects 226 and 228) consumes four grid units (e.g., grid units 258, 260, 262, and 264).

FIG. 3A is a diagram 300 illustrating a top view of an example MOS device 302 in accordance with various aspects of the disclosure. It should be understood that diagram 300 is a representation of the various masks that may be used for fabricating the features of the MOS device 302. For example, each mask may correspond to various features that are to be configured in a particular layer (e.g., gate interconnects, vias, etc) of the MOS device 302. Therefore, diagram 300 concurrently shows a number of layers of the MOS device 302 in an overlaid manner for ease of illustration and understanding of the disclosure.

MOS device 302 has a substrate surface 304 and diffusion regions 306, 308, 310, 312, 314, 316, 318, 320, and 322. As shown in FIG. 3A, the diffusion regions 306, 308, 310, 312, and 314 may be P diffusion regions, and diffusion regions 316, 318, 320, and 322 may be N diffusion regions. The MOS device 302 includes gate interconnects 324, 326, 328, and 330. In an aspect, the gate interconnects 324, 326, 328, and 330 may be configured in a POLY layer and may be referred to as POLY layer gate interconnects 324, 326, 328, and 330. The POLY layer gate interconnects 324, 326, 328, and 330 extend in a second direction as indicated in the top right corner of FIG. 3A. In the exemplary configuration of FIG. 3A, the POLY layer gate interconnects 324, 328, and 330 are configured as transistor gates. For example, POLY layer gate interconnect 324 is configured as a transistor gate for pMOS transistor 332 and nMOS transistor 338, POLY layer gate interconnect 328 is configured as a transistor gate for pMOS transistor 334, and POLY layer gate interconnect 330 is configured as a transistor gate for pMOS transistor 336 and nMOS transistor 340. POLY layer gate interconnect 326 may be configured as a dummy POLY gate interconnect.

As shown in FIG. 3A, the MOS device 302 further includes M1 layer interconnects 342, 344, and 346 configured in an M1 layer. As shown in FIG. 3A, the M1 layer interconnects 342, 344, and 346 extend in the first direction. In the configuration of FIG. 3A, the M1 layer interconnect 342 is coupled to the POLY layer gate interconnect 328 through via (V0_MG) and MP 350, and the M1 layer interconnect 344 is coupled to the POLY layer gate interconnect 324 through via (V0_MG) and MP 352.

As shown in FIG. 3A, the MOS device 302 further includes a metal diffusion two (MD2) layer interconnect 348 configured in the MD2 layer. In an aspect, the MD2 layer is situated below the M1 layer and above the POLY layer. The MD2 layer interconnect 348 extends between the POLY layer gate interconnects 326 and 328. In oxide diffusion (OD) regions, MD2 layer interconnects are used to contact diffusion regions (e.g., pMOS drain/source, nMOS drain/source). MD2 layer interconnects may be used in conjunction with metal diffusion one (MD1) layer interconnects to contact such diffusion regions. In OD regions, the MD2 layer interconnects are at the same height as metal POLY (MP) layer interconnects, and the MD1 layer interconnects are at the same height as POLY layer gate interconnects. In shallow trench isolation (STI) regions (non-OD regions), the MD2 layer interconnects may be used as local interconnects and may be formed higher than MD2 layer interconnects in the OD regions and with a nitride layer isolation. As shown in FIG. 3A, the M1 layer interconnect 342 is coupled to the M1 layer interconnect 346 through the MD2 layer interconnect 348. The MD2 layer interconnect 348 is coupled to the M1 layer interconnect 342 through via (V0_MD) 354. In the aspects disclosed herein, the term V0_MD refers to a via that is formed using metal and that couples an interconnect in an MD layer (e.g., MD2 layer) to an interconnect in a metal layer. As shown in FIG. 3A, the MD2 layer interconnect 348 is coupled to the M1 layer interconnect 346 through via (V0_MD) 356.

It should be noted that the configuration in FIG. 3A achieves the same functionality as the configuration of FIG. 2, while consuming a smaller area on a MOS device. More specifically, with reference to FIG. 3A, by implementing the MD2 layer interconnect 348, the configuration of FIG. 3A avoids the use of a POLY layer gate interconnect to achieve a connection between the M1 layer interconnect 342 and the M1 layer interconnect 346. This is in contrast to the configuration of FIG. 2, which requires the additional POLY layer gate interconnect 228 to achieve a connection between the M1 layer interconnect 244 and the M1 layer interconnect 248. As such, where the configuration of FIG. 2 consumes four grid units (e.g., grid units 258, 260, 262, and 264) on a MOS device, the configuration of FIG. 3A consumes three grid units (e.g., grid units 358, 360, and 362). Therefore, the configuration of FIG. 3A may provide area savings of at least one grid unit on the MOS device 302 as compared to the configuration of FIG. 2.

FIG. 3B is diagram 301 illustrating a cross-sectional view of the MOS device 302 at section A-A in FIG. 3A. In the configuration of FIG. 3B, the MP layer interconnect 351 is situated above the POLY layer gate interconnect 328, which couples the POLY layer gate interconnect 328 to the via (V0_MG) 350. MP layer interconnects may be formed of metal, and are used to contact POLY layer (gate) interconnects. The via (V0_MG) 350 couples the MP layer interconnect 351 to the M1 layer interconnect 342. It should be noted that in the aspect of FIG. 3B, the section A-A is located in a STI region of the MOS device 302. For example, the STI region may be formed by depositing a nitride layer 349 above the POLY and MP layers. Accordingly, in order to form the MD2 layer interconnect 348, a portion of the nitride layer portion 349 may be removed. Alternatively, an MD2 trench may be formed and then the nitride layer 349 formed along a wall and bottom surface of the MD2 trench. After the nitride layer portion 349 is formed, the MD2 layer interconnect 348 may be formed in the space of MD2 trench that is not filled in by the nitride layer portion 349. As shown in FIG. 3B, the MD2 layer interconnect 348 may be formed above and adjacent to remaining nitride layer portion 349 and may be electrically isolated from the MP layer in an STI region. In a diffusion region, the MD2 layer interconnect 348 may be at the same level as the MP layer 351 and not electrically isolated from the MP layer 351.

As shown in FIG. 3B, the via (V0_MD) 354 is formed above the MD2 layer interconnect 348 and the nitride layer portion 349. It should be noted that the via (V0_MD) 354 is extended in a horizontal direction so as to contact the via (V0_MG) 350. Therefore, the via (V0_MD) 354 couples the MD2 layer interconnect 348 to the via (V0_MG) 350. Thus, in the configuration of FIG. 3B, the M1 layer interconnect 342 is coupled to both the POLY layer gate interconnect 328 and the MD2 layer interconnect 348.

FIG. 3C is diagram 303 illustrating a cross-sectional view of the MOS device 302 at section A-A in FIG. 3A. The diagram 303 shown in FIG. 3C differs from the diagram 301 shown in FIG. 3B in that the via (V0_MD) 354 extends into the region occupied by the via (V0_MG) 350 seen in FIG. 3B. Optionally, the nitride layer portion 349 may be etched away and the (V0_MD) 354 may extend to contact the MD2 layer interconnect 348 on two sides.

FIG. 3D is diagram 305 illustrating a cross-sectional view of the MOS device 302 at section A-A in FIG. 3A. The diagram 305 shown in FIG. 3D differs from the diagram 301 shown in FIG. 3B in that the nitride layer portion 349 has been etched away, the via (V0_MG) 350 is smaller, and the via (V0_MD) 354 extends into the region occupied by the nitride layer region 349.

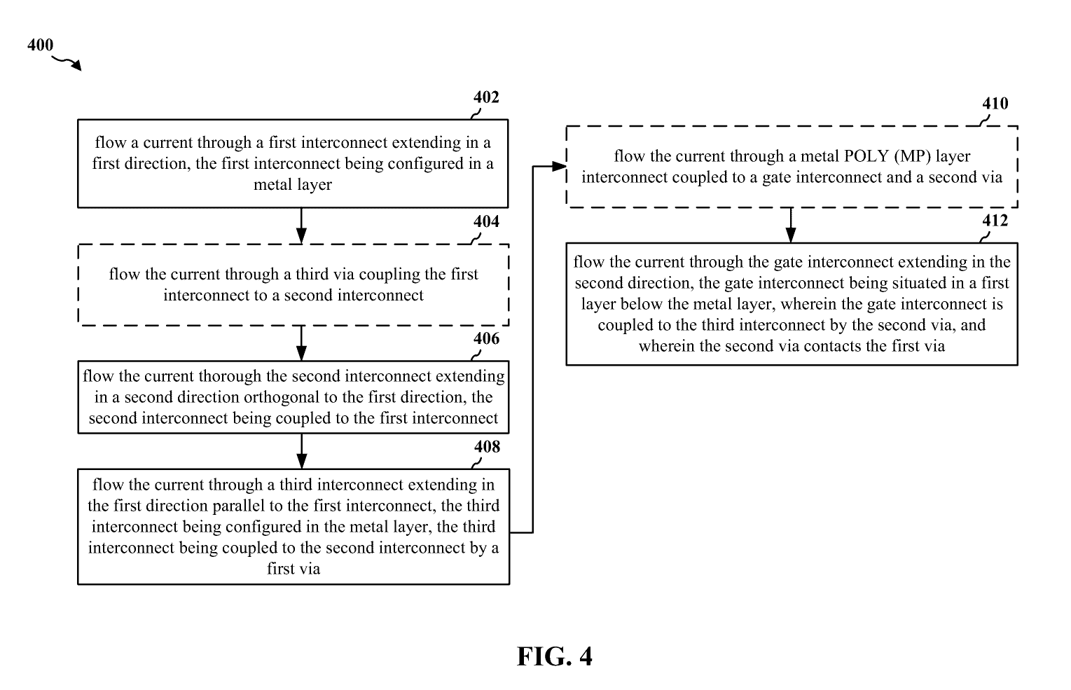

FIG. 4 is a flow chart 400 of an exemplary method. The exemplary method is a method of operation of a MOS device. Operations indicated with dashed lines represent optional operations for various aspects of the disclosure.

At 402, a current is flowed through a first interconnect extending in a first direction. In an aspect the first interconnect may be configured in a metal layer. For example, with reference to FIG. 3A, the first interconnect may be the M1 layer interconnect 346.

At 404, the current is flowed through a third via coupling the first interconnect to the second interconnect. For example, with reference to FIG. 3A, the third via may be via (V0_MD) 356.

At 406, the current is flowed through a second interconnect extending in a second direction orthogonal to the first direction. In an aspect, the second interconnect may be coupled to the first interconnect. For example, with reference to FIG. 3A, the second interconnect may be the MD2 layer interconnect 348.

At 408, the current is flowed through a third interconnect extending in the first direction parallel to the first interconnect. In an aspect, the third interconnect may be configured in the metal layer, the third interconnect being coupled to the second interconnect by a first via. For example, with reference to FIG. 3A, the third interconnect may be the M1 layer interconnect 342. For example, with reference to FIGS. 3A and 3B, the first via may be the via (V0_MD) 354. In an aspect, the third interconnect is configured in the MD layer. In an aspect, the third interconnect is situated in a second layer below the metal layer and above the first layer.

At 410, the current is flowed through an MP layer interconnect coupled to the gate interconnect and a second via. For example, with reference to FIG. 3B, the MP layer interconnect may be MP layer interconnect 351.

At 412, the current is flowed through a gate interconnect extending in the second direction. In an aspect, the gate interconnect may be situated in a first layer below the metal layer. In a further aspect, the gate interconnect may be coupled to the third interconnect by a second via. In yet another aspect, the second via may contact the first via. For example, with reference to FIG. 3A, the gate interconnect may be the POLY layer gate interconnect 328. In an aspect, a nitride layer is situated between the second interconnect and the second via.

In an aspect, a MOS device includes first means for flowing a current. In an aspect, the first means extend in a first direction. In a further aspect, the first means may be configured in a metal layer. For example, with reference to FIG. 3A, the first means may be the M1 layer interconnect 346.

The MOS device further includes second means for flowing the current. In an aspect, the second means extend in a second direction orthogonal to the first direction. In a further aspect the second means may be coupled to the first means. For example, with reference to FIG. 3A, the second means may be the MD2 layer interconnect 348.

The MOS device further includes third means for flowing the current. In an aspect, the third means extend in the first direction parallel to the first means. In a further aspect, the third means may be configured in the metal layer. In another aspect, the third means may be coupled to the second means by a first via. For example, with reference to FIG. 3A, the third means may be the M1 layer interconnect 342. In an aspect, the third means is situated in a second layer below the metal layer and above the first layer. In an aspect, the third means is configured in the MD layer.

The MOS device further includes fourth means for flowing the current. In an aspect, the fourth means extend in the second direction. In another aspect, the fourth means may be situated in a first layer below the metal layer. In a further aspect, the fourth means may be coupled to the third means by a second via. In yet another aspect, the second via may contact the first via. In still another an aspect, the fourth means may be configured as a gate contact. For example, with reference to FIG. 3A, the gate interconnect may be the POLY layer gate interconnect 328. In an aspect, a nitride layer is situated between the second means and the second via.

The MOS device further includes fifth means for flowing the current. In an aspect, the fifth means may be coupled to the fourth means and the second via. In another aspect, the fifth means may be configured in an MP layer. For example, with reference to FIG. 3B, the fifth means may be the MP layer interconnect 351.

The MOS device further includes sixth means for flowing the current. In an aspect, the sixth means may couple the first means to the second means. For example, with reference to FIG. 3A, the sixth means may be via (V0_MD) 356.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A metal oxide semiconductor (MOS) device, comprising:
a first interconnect extending in a first direction, the first interconnect being configured in a metal layer;
a second interconnect extending in the first direction parallel to the first interconnect, the second interconnect being configured in the metal layer;
a gate interconnect extending in a second direction orthogonal to the first direction, the gate interconnect being situated in a first layer below the metal layer, wherein the gate interconnect is coupled to the first interconnect by a first via; and
a third interconnect extending in the second direction, the third interconnect being coupled to both the first interconnect and the second interconnect, wherein the third interconnect is coupled to the first interconnect by a second via, and wherein the second via contacts the first via.

2. The MOS device of claim 1, wherein the third interconnect is configured in a metal diffusion (MD) layer.

3. The MOS device of claim 1, further comprising a metal POLY (MP) layer interconnect coupled to the gate interconnect and the first via.

4. The MOS device of claim 3, wherein the third interconnect is situated in a second layer below the metal layer and above the first layer.

5. The MOS device of claim 3, further comprising a third via coupling the second interconnect to the third interconnect.

6. The MOS device of claim 5, further comprising a nitride layer between the third interconnect and the first via.

7. A method of operation of a metal oxide semiconductor (MOS) device, comprising:
flowing a current through a first interconnect extending in a first direction, the first interconnect being configured in a metal layer;
flowing the current through a second interconnect extending in a second direction orthogonal to the first direction, the second interconnect being coupled to the first interconnect;
flowing the current through a third interconnect extending in the first direction parallel to the first interconnect, the third interconnect being configured in the metal layer, the third interconnect being coupled to the second interconnect by a first via; and
flowing the current through a gate interconnect extending in the second direction, the gate interconnect being situated in a first layer below the metal layer, wherein the gate interconnect is coupled to the third interconnect by a second via, and wherein the second via contacts the first via.

8. The method of claim 7, wherein the third interconnect is configured in a metal diffusion (MD) layer.

9. The method of claim 7, further comprising flowing the current through a metal POLY (MP) layer interconnect coupled to the gate interconnect and the second via.

10. The method of claim 9, wherein the third interconnect is situated in a second layer below the metal layer and above the first layer.

11. The method of claim 9, further comprising flowing the current through a third via coupling the first interconnect to the second interconnect.

12. The method of claim 11, wherein a nitride layer is situated between the second interconnect and the second via.

13. A metal oxide semiconductor (MOS) device, comprising:
first means for flowing a current, the first means extending in a first direction, the first means being configured in a metal layer;
second means for flowing the current, the second means extending in a second direction orthogonal to the first direction, the second means being coupled to the first means;
third means for flowing the current, the third means extending in the first direction parallel to the first means, the third means being configured in the metal layer, the third means being coupled to the second means by a first via; and
fourth means for flowing the current, the fourth means extending in the second direction, the fourth means being situated in a first layer below the metal layer, wherein the fourth means is coupled to the third means by a second via, and wherein the second via contacts the first via.

14. The MOS device of claim 13, wherein the third means is configured in a metal diffusion (MD) layer.

15. The MOS device of claim 13, further comprising fifth means for flowing the current, the fifth means coupled to the fourth means and the second via.

16. The MOS device of claim 15, wherein the fifth means is configured in a metal POLY (MP) layer.

17. The MOS device of claim 15, wherein the third means is situated in a second layer below the metal layer and above the first layer.

18. The MOS device of claim 15, further comprising sixth means for flowing the current, the sixth means coupling the first means to the second means.

19. The MOS device of claim 18, wherein a nitride layer is situated between the second means and the second via.

20. The MOS device of claim 13, wherein the fourth means is configured as a gate contact.
